(19) United States
(12) Patent Application Publication
(10) Pub. No.: US 2018/0366614 A1
(43) Pub. Date: Dec. 20, 2018

(54) MANGANESE-DOPED RED FLUORIDE PHOSPHOR, LIGHT EMITTING DEVICE, AND BACKLIGHT MODULE

(71) Applicant: Lextar Electronics Corporation, Hsinchu (TW)

(72) Inventors: Wei-Lun WU, Tainan City (TW); Yu-Chun LEE, Hsinchu County (TW); Ching-Yi CHEN, New Taipei City (TW); Tzong-Liang TSAI, Taichung City (TW); Mu-Huai FANG, Taoyuan City (TW); Ru-Shi LIU, New Taipei City (TW); Tsun-Hsiung YANG, Taichung City (TW); Chaochin SU, Taoyuan City (TW)

(21) Appl. No.: 15/993,616

(22) Filed: May 31, 2018

(30) Foreign Application Priority Data
Jun. 16, 2017 (TW) 106120244

(51) Int. Cl. H01L 33/06; H01L 33/50; F21V 9/38; H05B 33/14; C09K 11/57

(52) U.S. Cl. CPC H01L 33/06; H01L 33/504; C09K 11/57; H05B 33/14; F21V 9/38

(57) ABSTRACT

An emission spectrum of a manganese-doped red fluoride phosphor includes a zero phonon line crest and a crest. The zero phonon line crest has a first peak emission wavelength and a first intensity (I₁). The crest has a second peak emission wavelength and a maximum intensity (Iₘₐₓ) except for the zero phonon line crest. The second peak emission wavelength is greater than the first peak emission wavelength. A ratio (I₁/Iₘₐₓ) of the first intensity (I₁) to the maximum intensity (Iₘₐₓ) is ranged from about 0.2 to about 8 such that a luminous decay time of the manganese-doped red fluoride phosphor is less than 10 ms.

### RELATED APPLICATIONS

This application claims priority to Taiwan Application Serial Number 106120244, filed Jun. 16, 2017, which is herein incorporated by reference.

### BACKGROUND

### Field of Invention

The present invention relates to a manganese-doped red fluoride phosphor, a light emitting device, and a backlight module.

### Description of Related Art

In recent years, the rise of electronic products also increases the demand for backlight displays in the world, for example color TVs, billboards, mobile phone screen. With the development of the backlight industry, the backlight displays with high color resolution, high efficiency, and high frequency are actively developed. Currently, the phosphors with a narrow spectral emission is used commonly in backlight displays to obtain a higher color purity and a stronger radiation intensity of the light source, and then the display with high efficiency and large color gamut may be developed. The traditional red phosphor has a longer luminous decay time which is more than 10 ms due to the Laporte rule. The longer luminous decay time may cause the residual of red light in the display, and then the application of the red phosphor is limited.

### SUMMARY

The present disclosure provides a manganese-doped red fluoride phosphor. An emission spectrum of the manganese-doped red fluoride phosphor includes a zero phonon line crest and a crest. The zero phonon line crest has a first peak emission wavelength and a first intensity (I₁). The crest has a second peak emission wavelength and a maximum intensity (Iₘₐₓ) except for the zero phonon line crest. The second peak emission wavelength is greater than the first peak emission wavelength. A ratio (I₁/Iₘₐₓ) of the first intensity (I₁) to the maximum intensity (Iₘₐₓ) is ranged from about 0.2 to about 8 such that a luminous decay time of the manganese-doped red fluoride phosphor is less than 10 ms.

In some embodiments of the present disclosure, the manganese-doped red fluoride phosphor is one or more phosphors selected from the group consisting of:

(A) A₂[MF₆]:Mn⁴⁺, wherein A is one or more materials selected from the group consisting of Li, Na, K, Rb, Cs, and NH4, M includes one or more materials selected from the group consisting of Ge, Si, Sn, Ti, and Zr;
(B) A₃[MF₆]:Mn⁴⁺, wherein A is one or more materials selected from the group consisting of Li, Na, K, Rb, Cs, and NH4, M includes one or more materials selected from the group consisting of Al, Ga, and In; and
(C) A₃[HMF₈]:Mn⁴⁺, wherein A is one or more materials selected from the group consisting of Li, Na, K, Rb, Cs, and NH₄, and M comprises one or more materials selected from the group consisting of Ti, Si, and Ge.

In some embodiments of the present disclosure, the Mn⁴⁺ in the manganese-doped red fluoride phosphor has a doping ratio ranged from about 0.5 to 20 atom % (at. %).

In some embodiments of the present disclosure, a concentration of the Mn⁴⁺ in the manganese-doped red fluoride phosphor is ranged from about 3 mol % to about 10 mol %.

In some embodiments of the present disclosure, the manganese-doped red fluoride phosphor has a chemical formula below:

Na₂SiₓGe₁₋ₓF₆:Mn⁴⁺ or Na₂Ge_{y}Ti_{1-y}F₆:Mn⁴⁺, wherein 0≤x≤1 and 0≤y≤1; and

Na₃HTi₁₋ₓF₈:Mn⁴⁺, wherein 0<x≤0.09.

In some embodiments of the present disclosure, the first peak emission wavelength of the zero phonon line crest is ranged from about 615 nm to about 620 nm.

In some embodiments of the present disclosure, the crest is a V6 emission crest (Stokes shift).

The present disclosure provides a light emitting device. The light emitting device includes a light emitting element and a phosphor material. The phosphor material includes the manganese-doped red fluoride phosphor as described above.

In some embodiments of the present disclosure, the phosphor material further includes one or more phosphors and/or quantum dots.

In some embodiments of the present disclosure, the light emitting device further includes an encapsulant. The phosphor material is dispersed in the encapsulant.

The present disclosure provides a backlight module. The backlight module includes the light emitting device as described above.

### BRIEF DESCRIPTION OF THE DRAWINGS

The invention can be more fully understood by reading the following detailed description of the embodiment, with reference made to the accompanying drawings as follows:

FIG. 1A is an excitation spectrum of the light emitting element in accordance with various embodiments of the present disclosure.

FIG. 1B is a radiation spectrum of Na₂TiF₆:Mn⁴⁺ in accordance with various embodiments of the present disclosure.

FIG. 2 is a luminous decay curve of Na₂TiF₆:Mn⁴⁺ in accordance with various embodiments of the present disclosure.

FIG. 3 is a XRD diffraction chart of solid solution of Na₂SiₓGe₁₋ₓF₆:Mn⁴⁺ and Na₂Ge_{y}Ti_{1-y}F₆:Mn⁴⁺ in accordance with various embodiments of the present disclosure.

FIG. 4 is a radiation spectrum of solid solutions of Na₂SiₓGe₁₋ₓF₆:Mn⁴⁺ and Na₂Ge_{y}Ti_{1-y}F₆:Mn⁴⁺ in accordance with various embodiments of the present disclosure.

FIG. 5 is a chart illustrating the relationship between luminous decay time and intensity ratio in accordance with various embodiments of the present disclosure.

FIG. 6A-6E is a radiation spectrum of Na₂TiF₆:Mn⁴⁺ in different Mn⁴⁺ concentration in accordance with various embodiments of the present disclosure.

FIG. 6F is a chart illustrating the relationship between external quantum efficiency and the Mn⁴⁺ concentration for Na₂TiF₆:Mn⁴⁺ in accordance with various embodiments of the present disclosure.

FIG. 7 is a chart illustrating the relationship between luminous decay time and external quantum efficiency for different Mn⁴⁺ concentration Na₂TiF₆:Mn⁴⁺ in accordance with various embodiments of the present disclosure.

FIG. 8A-8G is a radiation spectrum of 5 mol % Mn⁴⁺ of Na₂TiF₆:Mn⁴⁺ formed in different temperature in accordance with various embodiments of the present disclosure.

FIG. 8H is a chart illustrating the relationship between spectral relatively intensity and temperature for 5 mol % Mn⁴⁺ of Na₂TiF₆:Mn⁴⁺ in accordance with various embodiments of the present disclosure.

FIG. 9 is a radiation spectrum of Na₃HTiF₈:Mn⁴⁺ in accordance with various embodiments of the present disclosure.

FIG. 10A-10E is a radiation spectrum of Na₃HTiF₈:Mn⁴⁺ in different Mn⁴⁺ concentration in accordance with various embodiments of the present disclosure.

FIG. 11A-11G is a radiation spectrum of 5 mol % Mn⁴⁺ of Na₃HTiF₈:Mn⁴⁺ formed in different temperature in accordance with various embodiments of the present disclosure.

FIG. 11H is a chart illustrating the relationship between spectral relatively intensity and temperature for 5 mol % Mn⁴⁺ of Na₃HTiF₈:Mn⁴⁺ in accordance with various embodiments of the present disclosure.

FIG. 12 is a cross-section view of the light emitting device in accordance with various embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

The present disclosure provides a red phosphor having a luminous decay time of less than 10 ms, thereby preventing the human eye from the observation of the residual light of the red phosphor in the high frequency display. To be specific, the red phosphor is a manganese-doped red fluoride phosphor with a chemical formula of A₂[MF₆]:Mn⁴⁺, A₃[MF₆]:Mn⁴⁺, or A₃[HMF₈]:Mn⁴⁺. When the chemical formula of the manganese-doped red fluoride phosphor is A₂[MF₆]:Mn⁴⁺, A is one or more materials selected from the group consisting of Li, Na, K, Rb, Cs, and NH₄, and M includes one or more materials selected from the group consisting of Ge, Si, Sn, Ti, and Zr. When chemical formula of the manganese-doped red fluoride phosphor is A₃[MF₆]:Mn⁴⁺, A is one or more materials selected from the group consisting of Li, Na, K, Rb, Cs, and NH₄, and M includes one or more materials selected from the group consisting of Al, Ga, and In. When chemical formula of the manganese-doped red fluoride phosphor is A₃[HMF₈]:Mn⁴⁺, A is one or more materials selected from the group consisting of Li, Na, K, Rb, Cs, and NH₄, and M includes one or more materials selected from the group consisting of Ti, Si, and Ge. To be specific, the doping ratio of the manganese-doped ion (Mn⁴⁺) in the manganese-doped red fluoride phosphor is ranged from about 0.5 to about 20 atom % (at. %). For example, the doping ratio of Mn⁴⁺ may be 1 at. %, 3 at. %, 5 at. %, 7 at. %, 9 at. %, 11 at. %, 13 at. %, 15 at. %, 17 at. %, or 19 at. %.

In one embodiment, the present disclosure provides a method for synthesizing the manganese-doped red fluoride phosphor with chemical formula A₂[MF₆]:Mn⁴⁺ by the chemical coprecipitation method. First, a M ion-containing precursor of MO₂ and/or M(OC₃H₇)₄, which may be mixed with each other in different proportions, in a total molar number of about 0.01 mole is mixed with 10 mL of HF to form a first solution containing MF₆²⁻, where M is one or more materials selected from Ge, Si, Sn, Ti, and Zr. For example, MO₂ may be GeO₂, SiO₂, or Ti(OC₃H₇)₄, but not limited thereto. Next, 2 g of the AF is added to 20 mL HF, and the AF is completely dissolved in HF to form a second solution, that is excess A ions solution, where A is one or more materials selected from Li, Na, K, Rb, Cs, and NH₄. For example, AF may be LiF, NaF, KF, NH₄F, LiNaF, NaKF, or LiKF, but not limited thereto. 0.32 mmole K₂MnF₆, serving as an activator, is added to the second solution to form a third solution. The first solution is mixed with the third solution at room temperature, and at this time, a precipitate A₂[MF₆]:Mn⁴⁺ is formed in the mixed solution. The precipitate A₂[MF₆]:Mn⁴⁺ is collected by decantation. Next, the precipitate is washed with alcohol and acetone and placed in an oven at 55° C. to dry it, so that the manganese-doped red fluoride phosphor may be obtained.

In another embodiment, the present disclosure provides a method for synthesizing the manganese-doped red fluoride phosphor with chemical formula Na₃HTiF₈:Mn⁴⁺ by the chemical coprecipitation method. First, 1.62 g of the NaF is added to 18 mL of HF. After NaF is completely dissolved in HF, 0.1090 g of K₂MnF₆, serving as an activator, is added to form a first solution. Next, 3 mL of Ti(OC₃H₇)₄ is dissolved in 5 mL of HF and the methanol is added to form a second solution. The first solution is then mixed with the second solution at room temperature, and at this time, a precipitate Na₃HTiF₈:Mn⁴⁺ is formed in the mixed solution. The precipitate Na₃HTiF₈:Mn⁴⁺ is collected by decantation. Next, the precipitate is washed with alcohol and acetone and placed in an oven at 60° C. to dry it 5 hours, so that the manganese-doped red fluoride phosphor with chemical formula Na₃HTiF₈:Mn⁴⁺ may be obtained.

In some embodiments, the manganese-doped red fluoride phosphor may have a chemical formula of Na₂SiₓGe₁₋ₓF₆:Mn⁴⁺ or Na₂Ge_{y}Ti_{1-y}F₆:Mn⁴⁺, where 0≤x≤1 and 0≤y≤1.

In some embodiments, the manganese-doped red fluoride phosphor may also have a chemical formula of Na₃HTi₁₋ₓ F₈:Mn⁴⁺, wherein 0<x≤0.09.

In some embodiments, the luminous decay time of the manganese-doped red fluoride phosphor is less than 10 ms, and the emission spectrum of the manganese-doped red fluoride phosphor includes a zero phonon line crest and another crest. To be specific, the zero phonon line crest has a first peak emission wavelength and a first intensity (I₁), and the first peak emission wavelength is ranged from about 615 nm to about 620 nm. The another crest has a second peak emission wavelength and a maximum intensity (Iₘₐₓ) except for the zero phonon line crest, and the second peak emission wavelength is ranged from about 622 nm to about 635 nm. To be specific, the another crest is defined as the peak with the highest intensity except for the zero phonon line crest in the emission spectrum of the manganese-doped red fluoride phosphor. It should be noted that the second peak emission wavelength is greater than the first peak emission wavelength, and the ratio (I₁/Iₘₐₓ) of the first intensity (I₁) to the maximum intensity (Iₘₐₓ) is ranged from about 0.2 to about 8. The ratio may be 0.5, 1, 1.5, 2, 2.5, 3, 3.5, 4, 4.5, 5, 5.5, 6, 6.5, 7, or 7.5, for example.

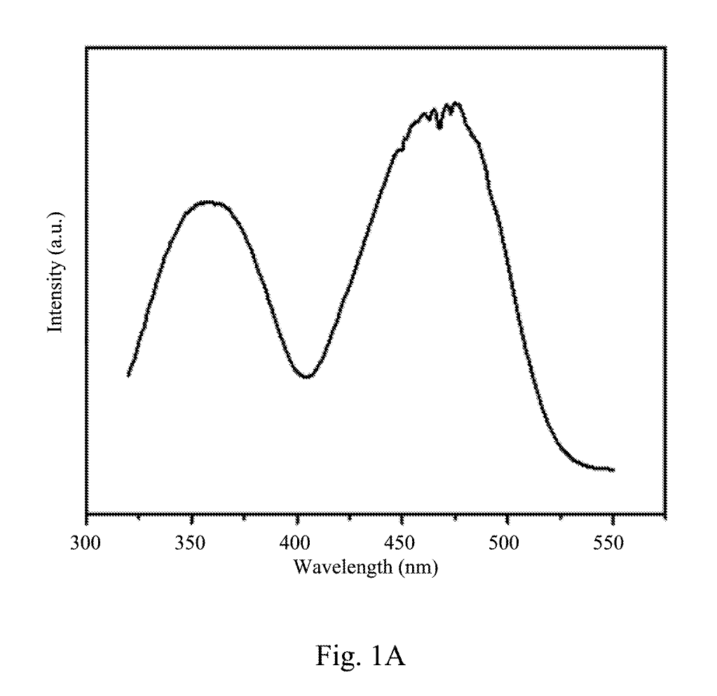

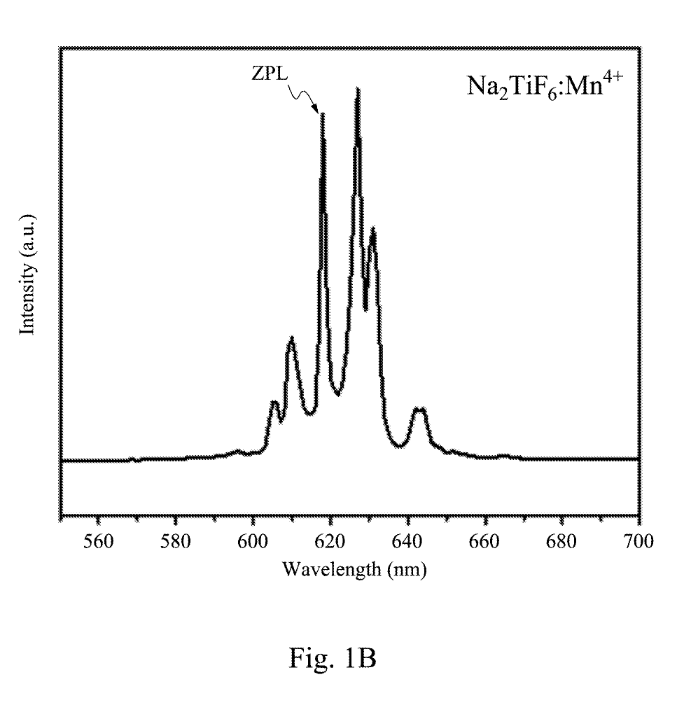

Please refer to FIG. 1A and FIG. 1B. FIG. 1A is an excitation spectrum of a light emitting element in accordance with various embodiments of the present disclosure. FIG. 1B is a radiation spectrum of Na₂TiF₆:Mn⁴⁺ in accordance with various embodiments of the present disclosure. In one embodiment, the light emitting element is a light-emitting diode (LED), which may emit a blue light having an excited wavelength in a range of about 420 nm to about 480 nm as shown in FIG. 1A, and the manganese-doped red fluoride phosphor is a Na₂TiF₆:Mn⁴⁺ phosphor. The red phosphor may emit a red light having a wavelength in a range of about 600 nm to about 650 nm as shown in FIG. 1B while being excited by the blue LED. In the emission spectrum of the Na₂TiF₆:Mn⁴⁺ phosphor, the Na₂TiF₆:Mn⁴⁺ phosphor has a zero phonon line ZPL, and a peak emission wavelength of the zero phonon line crest is ranged from about 615 nm to about 620 nm.

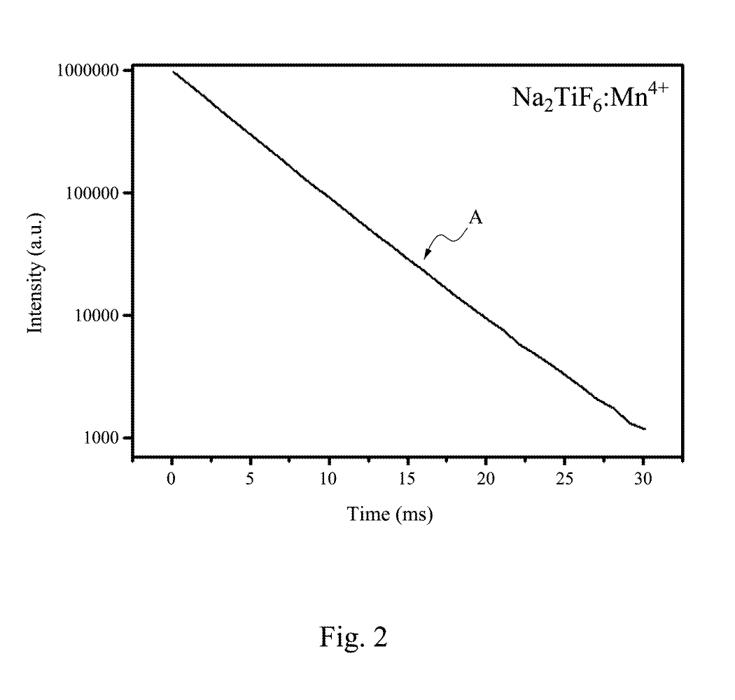

Referring to FIG. 2, which illustrates a luminous decay curve of Na₂TiF₆:Mn⁴⁺ in accordance with various embodiments of the present disclosure. The curve A in FIG. 2 is a luminous decay curve of Na₂TiF₆:Mn⁴⁺. The theoretical luminous decay time is calculated according to the formula of decay of fluorescence shown below: I=I₀exp(−t/τ), where I₀ is the initial luminous intensity at t=0, I is the luminous intensity at time t, and τ is luminous decay time. The curve A may be to calculate the luminous decay time of the Na₂TiF₆:Mn⁴⁺ phosphor, and the calculated result is about 4.02 ms, according to the formula above. Therefore, the Na₂TiF₆:Mn⁴⁺ phosphor may be applied to advanced backlight displays with a high frequency of 240 Hz, and the backlight displays are free from the residual of red light.

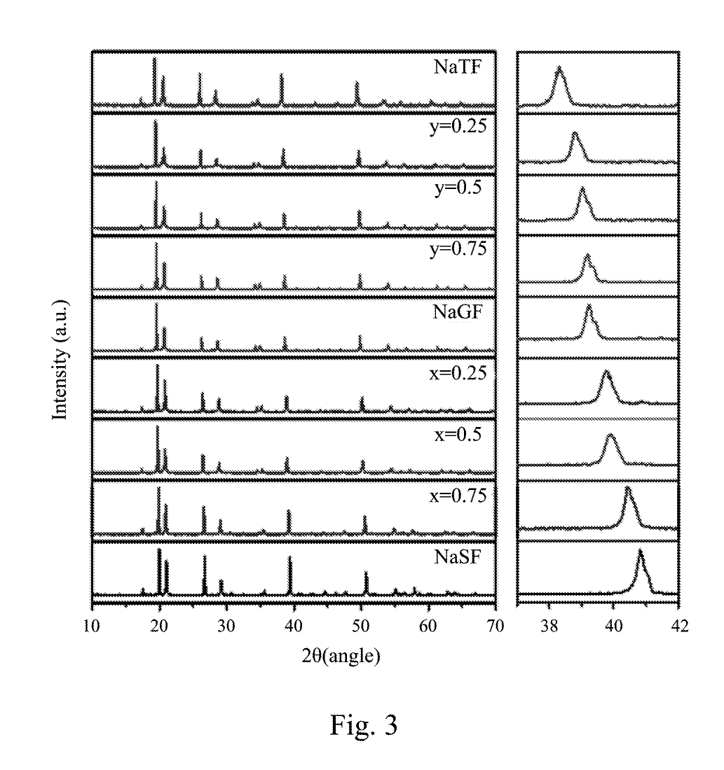

Referring to FIG. 3, which illustrates X-Ray Diffraction (XRD) diffraction charts of the solid solution of Na₂SiₓGe₁₋ₓF₆:Mn⁴⁺ and Na₂Ge_{y}Ti_{1-y}F₆:Mn⁴⁺ in accordance with various embodiments of the present disclosure. The chemical coprecipitation method described above is used to form a series of solid solutions of Na₂SiₓGe₁₋ₓF₆:Mn⁴⁺ and Na₂Ge_{y}Ti_{1-y}F₆:Mn⁴⁺, for example, Na₂TiF₆:Mn⁴⁺, Na₂Ge_{0.25}Ti_{0.75}F₆:Mn⁴⁺, Na₂Ge_{0.5}Ti_{0.5}F₆:Mn⁴⁺, Na₂Ge_{0.75}Ti_{0.25}F₆:Mn⁴⁺, Na₂GeF₆:Mn⁴⁺, Na₂Si_{0.25}Ge_{0.75}F₆:Mn⁴⁺, Na₂Si_{0.5}Ge_{0.5}F₆:Mn⁴⁺, Na₂Si_{0.75}Ge_{0.25}F₆:Mn⁴⁺, and Na₂SiF₆:Mn⁴⁺. It may be confirmed from the XRD diffraction charts that the series of synthesis samples of Na₂SiₓGe₁₋ₓF₆:Mn⁴⁺ and Na₂Ge_{y}Ti_{1-y}F₆:Mn⁴⁺ mentioned above are pure-phase structures (single-phase structures). In addition, when the manganese-doped red fluoride phosphors are transformed from Na₂TiF₆:Mn⁴⁺ to Na₂GeF₆:Mn⁴⁺ and further transformed to Na₂SiF₆:Mn⁴⁺, the diffraction angle (2θ) of one of the peaks increases from 38 degrees to 41 degrees as shown in FIG. 3. That is, when the atomic species and the proportions thereof in the host lattice (Na₂SiₓGe₁₋ₓF₆ or Na₂Ge_{y}Ti_{1-y}F₆) are changed, a portion of lattice structure of the manganese-doped red fluoride phosphor are distorted, as illustrated in the XRD diffraction charts.

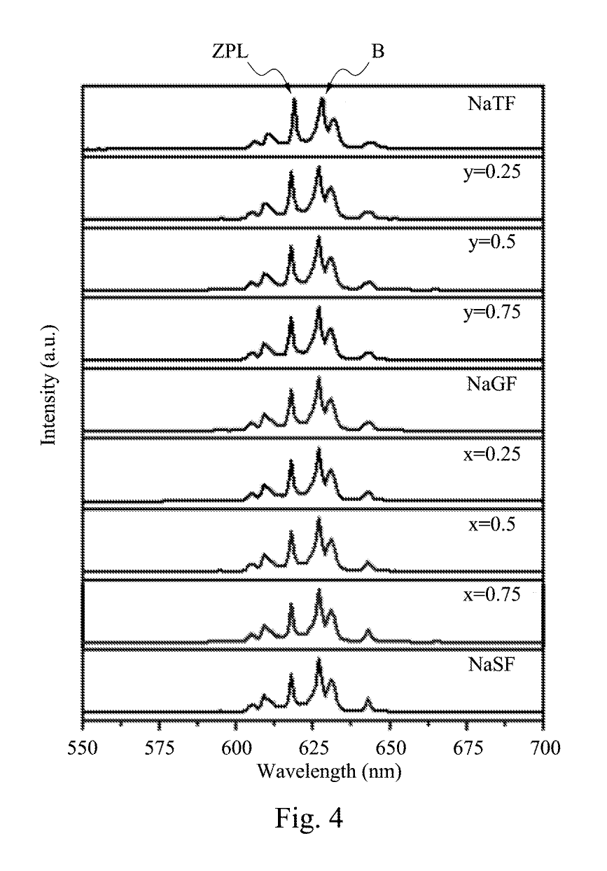

Referring to FIG. 4, which illustrates the radiation spectrums of the solid solutions of Na₂SiₓGe₁₋ₓF₆:Mn⁴⁺ and Na₂Ge_{y}Ti_{1-y}F₆:Mn⁴⁺ in accordance with various embodiments of the present disclosure. The manganese-doped red fluoride phosphor samples in FIG. 4 correspond to the manganese-doped red fluoride phosphor samples in FIG. 3. The Na₂SiₓGe₁₋ₓF₆:Mn⁴⁺ and Na₂Ge_{y}Ti_{1-y}F₆:Mn⁴⁺ manganese-doped red fluoride phosphors have a zero phonon line at the wavelength ranged from about 615 nm to about 620 nm shown in FIG. 4 and have a peak B at the wavelength ranged from about 622 nm to about 635 nm. The zero phonon line ZPL may greatly increase the area of the red light emitting spectrum of the manganese-doped red fluoride phosphor, and the color rendering index (CRI) of the light emitting device using the phosphor may be further improved. More specifically, the crest B is defined as the peak having the largest intensity except for the zero phonon line crest in the present invention. In one embodiment, the crest B is a V6 emission crest. It may be seen clearly in FIG. 4 that when the manganese-doped red fluoride phosphor sample is transformed from Na₂TiF₆:Mn⁴⁺ to Na₂GeF₆:Mn⁴⁺ and then transformed to Na₂SiF₆:Mn⁴⁺, the intensity of the zero phonon line crest has a tendency to be decreased gradually. Therefore, the distortion degree of the lattice of the manganese-doped red fluoride phosphor may be effectively adjusted by modulating the atomic species and the proportions thereof in the host lattice so to obtain the required peak intensity of the zero phonon line.

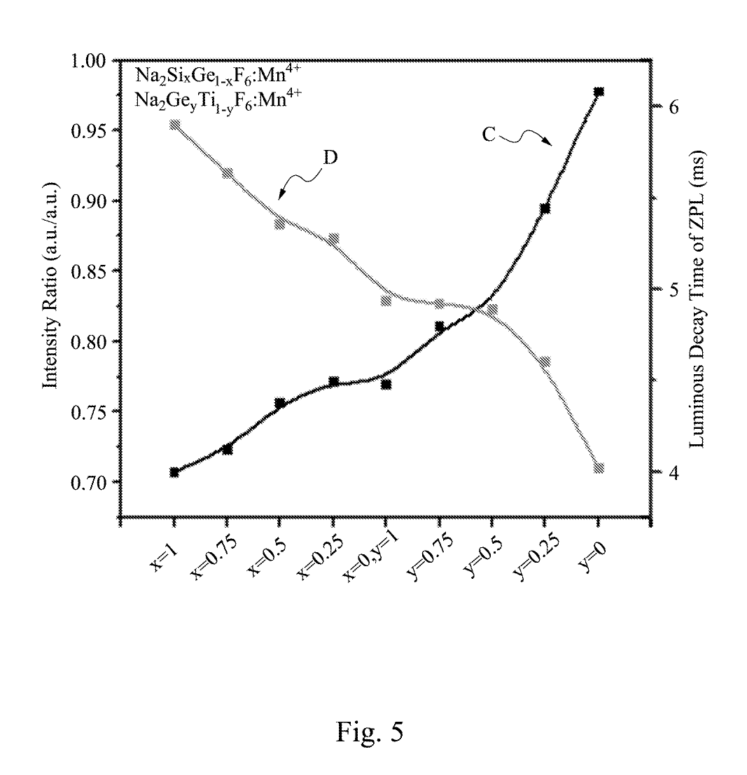

FIG. 5 is a chart illustrating the relationship between luminous decay time and intensity ratio in accordance with various embodiments of the present disclosure. The manganese-doped red fluoride phosphor samples associated with FIG. 5 correspond to the manganese-doped red fluoride phosphor samples illustrated in FIG. 3 and FIG. 4. The curve C in FIG. 5 represents the intensity ratio of the zero phonon line to the V6 emission crest of the manganese-doped red fluoride phosphor samples, and the curve D represents the luminous decay time of the manganese-doped red fluoride phosphor samples. It may be seen in FIG. 5 that the intensity ratio of the curve C increases gradually from about 0.70 to about 0.98 and the luminous decay time of the curve D decreases gradually from about 6 ms to about 4 ms when the manganese-doped red fluoride phosphor is transformed from Na₂SiF₆:Mn⁴⁺ to Na₂GeF₆:Mn⁴⁺ and then transformed to Na₂TiF₆:Mn⁴⁺. With the increase in the emission intensity of the zero phonon line crest, the radiation relaxation rate of electronics may be effectively improved, thereby shortening the luminous decay time of the manganese-doped red fluoride phosphor. Moreover, by varying the emission intensity ratio of the zero phonon line to the V6 emission crest, the manganese-doped red fluoride phosphor may solve the problem of the residual of red light in the commercialized display with high frequency, such as 120 Hz and/or 240 Hz.

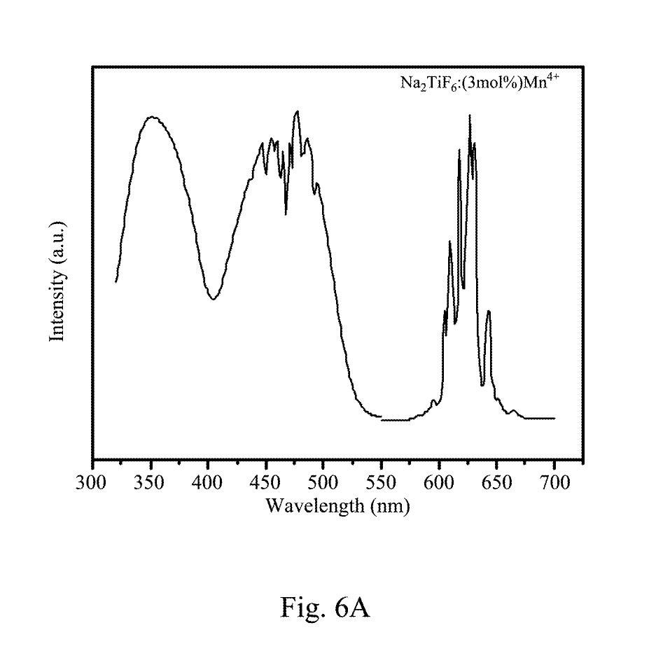

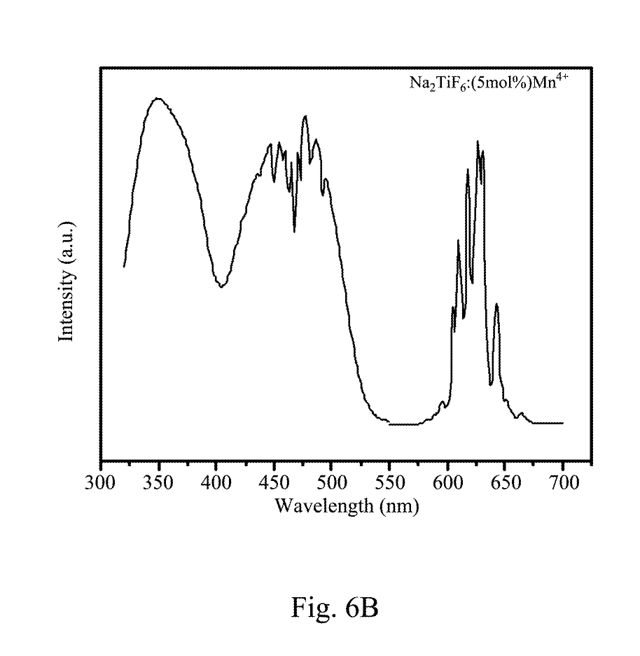

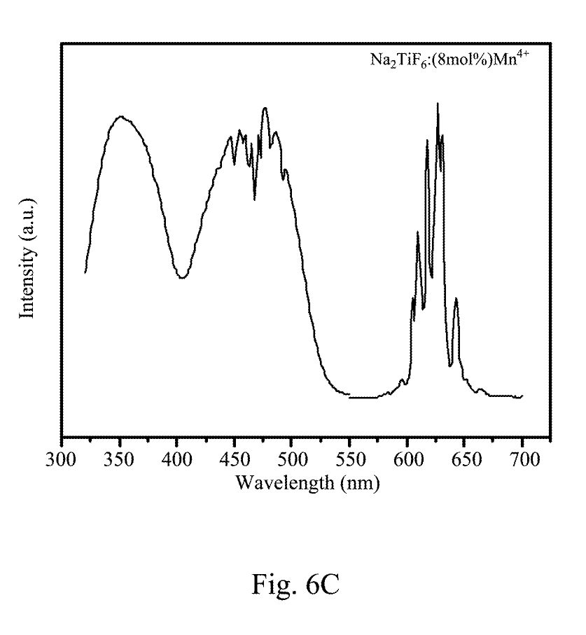

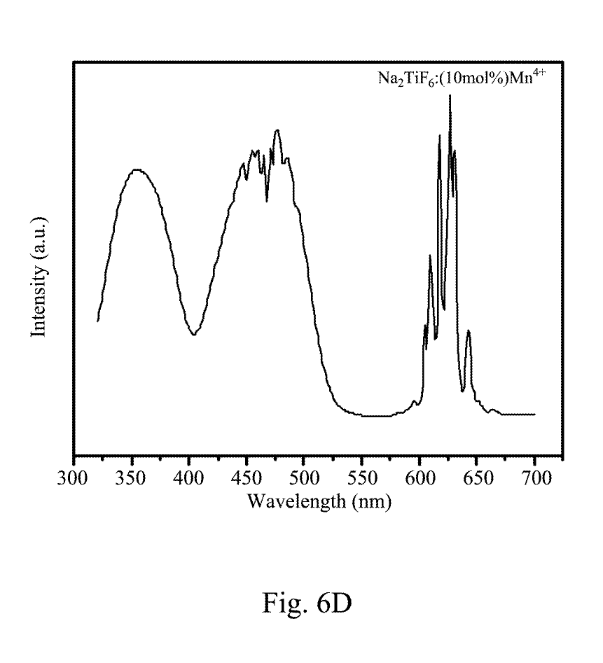

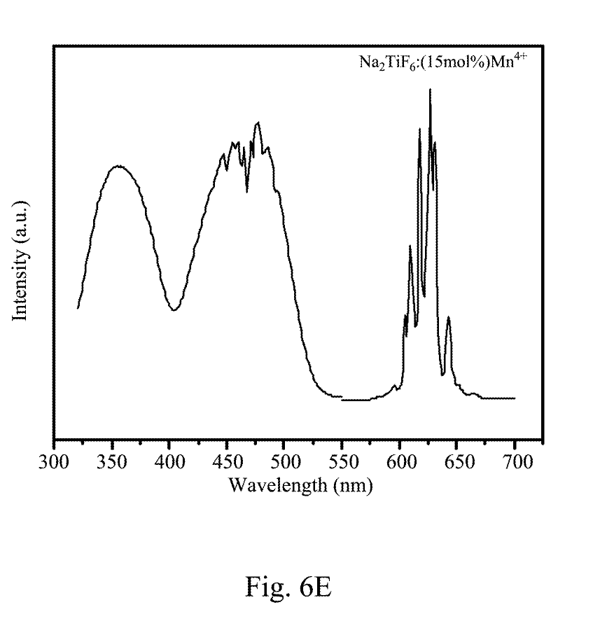

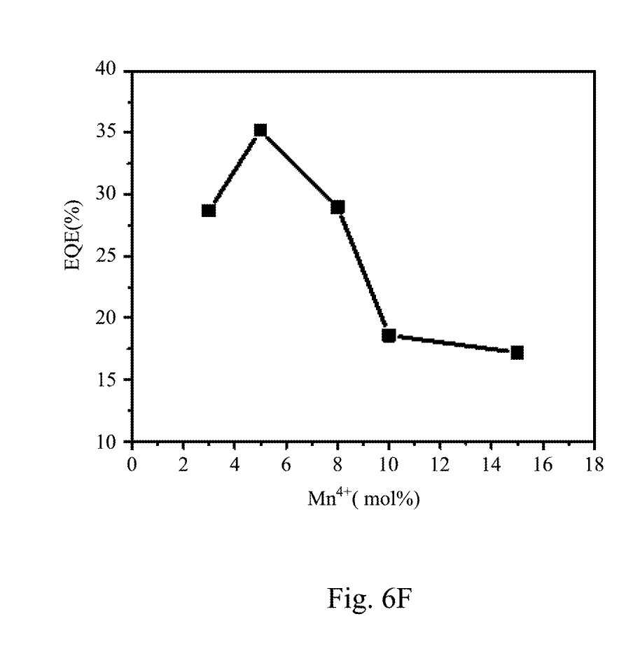

FIG. 6A-6E show radiation spectrum of Na₂TiF₆:Mn⁴⁺ with different Mn⁴⁺ concentration in accordance with various embodiments of the present disclosure. The Na₂TiF₆:Mn⁴⁺ red fluoride phosphor has the zero phonon line at the wavelength ranged from about 615 nm to about 620 nm as described above. In FIG. 6A-6E, it can be clearly observed that the zero phonon line of the Na₂TiF₆:Mn⁴⁺ red fluoride phosphor has the maximum intensity when the concentration of Mn⁴⁺ is 5 mol %.

FIG. 6F is a chart illustrating the relationship between the external quantum efficiency (EQE) and the Mn⁴⁺ concentration of Na₂TiF₆:Mn⁴⁺ in accordance with various embodiments of the present disclosure. The Mn⁴⁺ concentration in FIG. 6F corresponds to the Mn⁴⁺ concentration in FIG. 6A-6E. The external quantum efficiency of the Na₂TiF₆:Mn⁴⁺ red fluoride phosphor with the Mn⁴⁺ concentration of 3 mol %, 5 mol %, 8 mol %, 10 mol %, and 15 mol % is about 28.7%, 35.2%, 29.0%, 21.2%, and 17.2% respectively. It noted that the luminous efficiency of the Na₂TiF₆:Mn⁴⁺ red fluoride phosphor with the Mn⁴⁺ concentration of 5 mol % is much better than other Mn⁴⁺ concentrations.

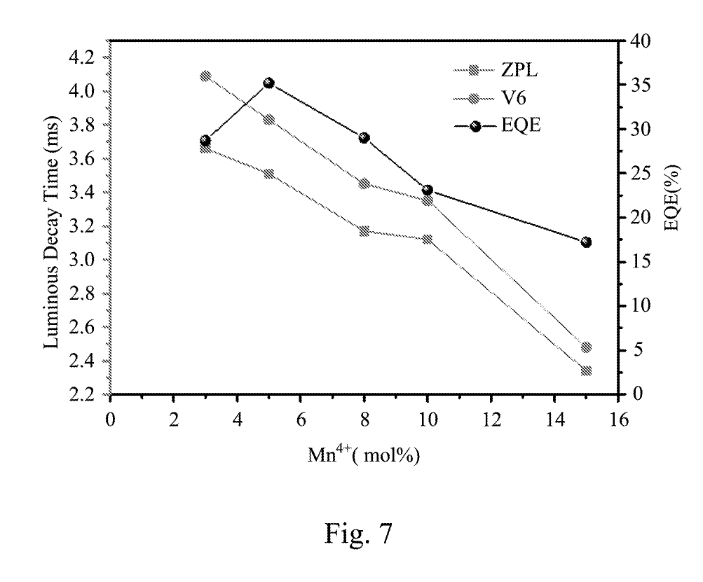

FIG. 7 is a chart illustrating the relationship between luminous decay time and external quantum efficiency for different Mn⁴⁺ concentration Na₂TiF₆:Mn⁴⁺ in accordance with various embodiments of the present disclosure. In FIG. 7, it can be clearly observed that the luminous decay time of the zero phonon line crest and the V6 emission crest are decreased gradually (from about 3.66 ms to about 2.36 ms and from about 4.08 ms to about 2.50 ms respectively) with the increase of Mn⁴⁺ concentration (from about 3 mol % to about 15 mol %). In other words, no matter how much the Mn⁴⁺ concentration of the Na₂TiF₆:Mn⁴⁺ is, the luminous decay time of the Na₂TiF₆:Mn⁴⁺ red fluoride phosphor is less than 10 ms, even less than 4.2 ms. However, the Na₂TiF₆:Mn⁴⁺ red fluoride phosphor has the highest external quantum efficiency about 35.2% at the Mn⁴⁺ concentration of 5 mol %. The low external quantum efficiency may cause an increase in energy consumption. Therefore, when the Na₂TiF₆:Mn⁴⁺ red fluoride phosphor has a Mn⁴⁺ concentration in the range of about 3 mol % to about 10 mol %, the external quantum efficiency is usually 21.2% or more, preferably 28.7% or more, and more preferably 35.2% or more.

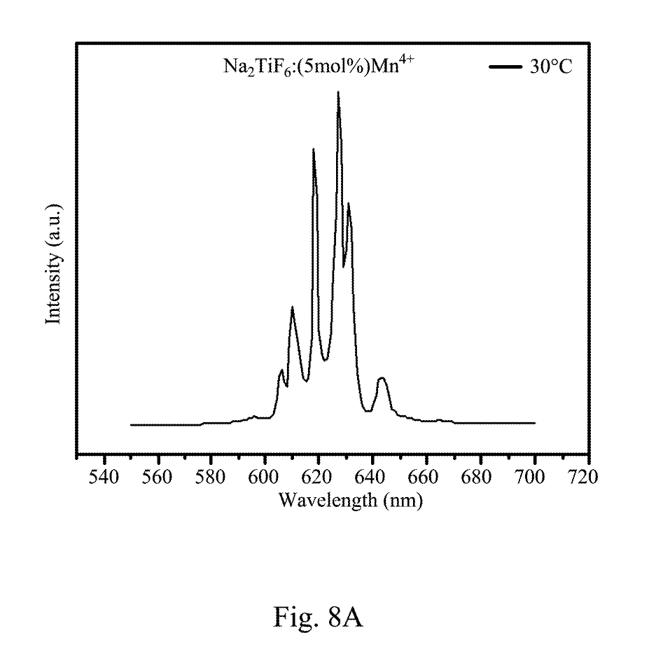

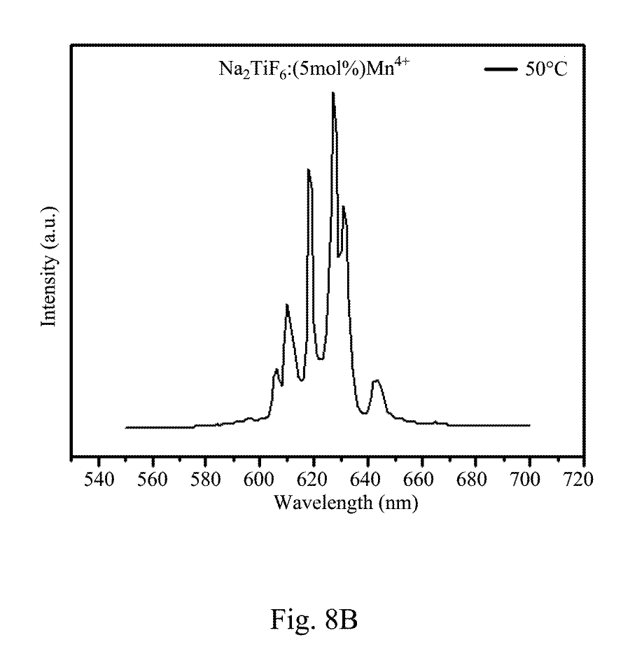

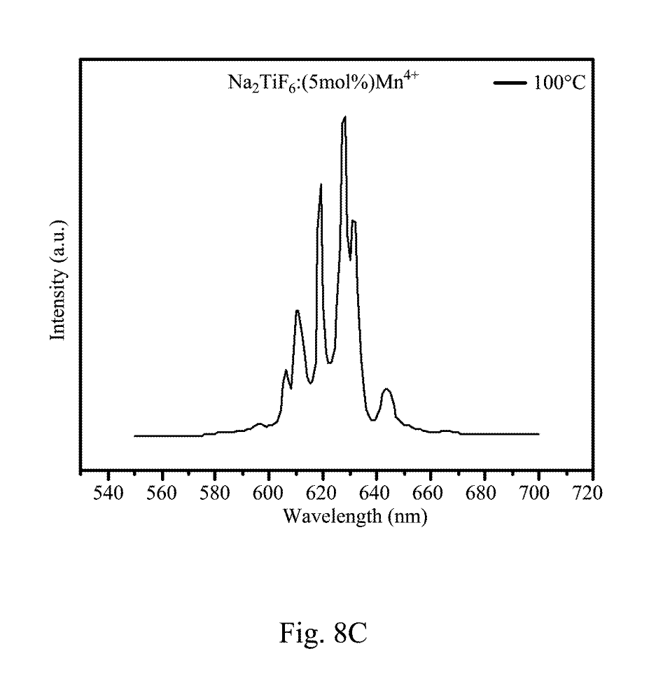

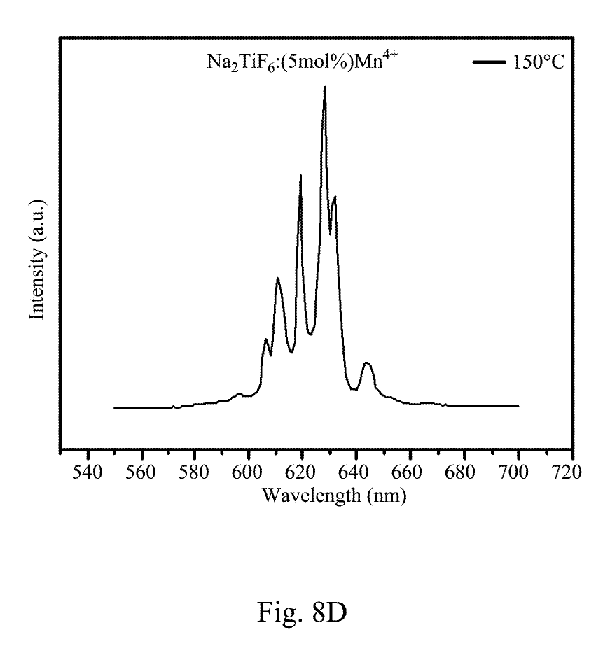

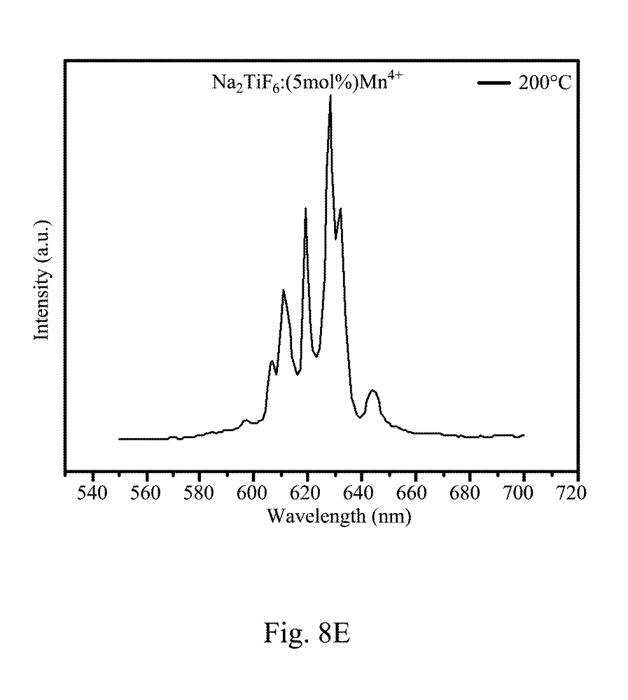

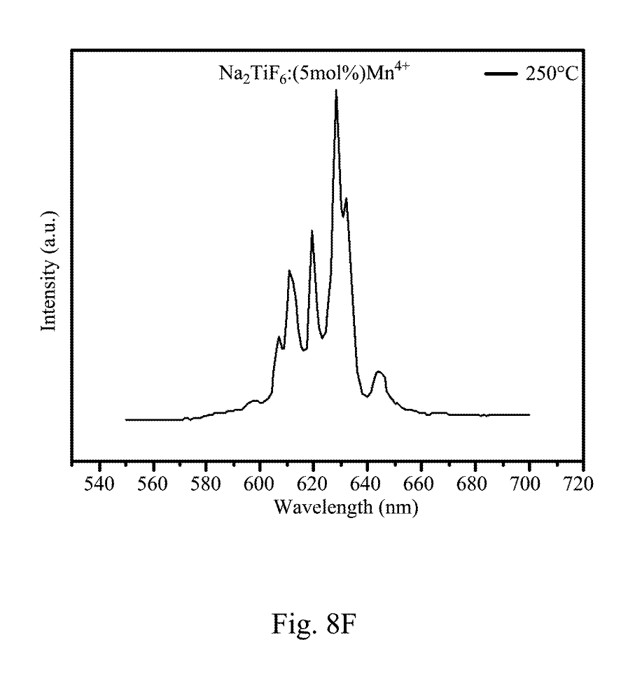

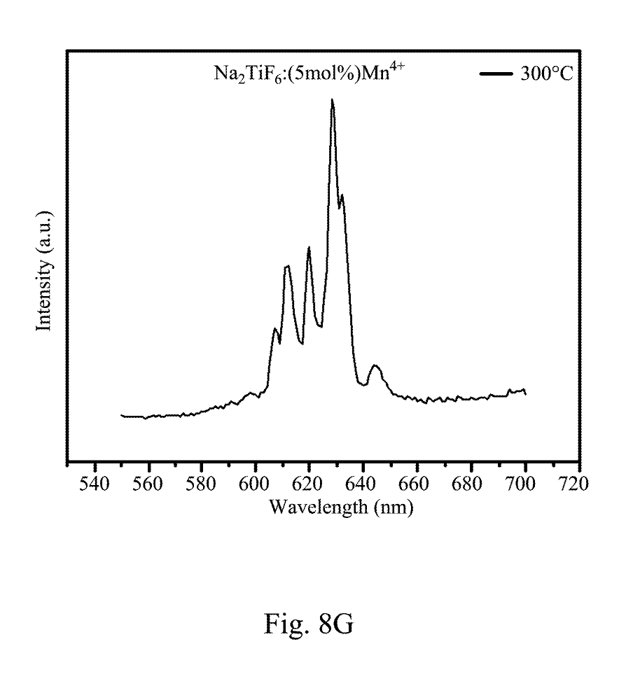

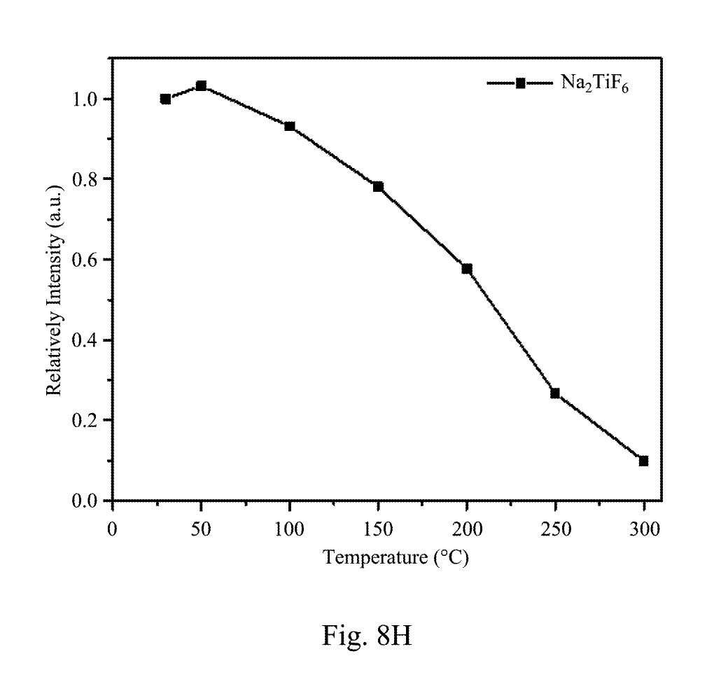

Referring to FIG. 8A-8G, which are radiation spectrums of 5 mol % Mn⁴⁺ of Na₂TiF₆:Mn⁴⁺ manufactured at different temperatures in accordance with various embodiments of the present disclosure. The Na₂TiF₆:Mn⁴⁺ red fluoride phosphor has the zero phonon line at the wavelength ranged from about 615 nm to about 620 nm as described above. In FIG. 8A-8G, it can be clearly observed that when the temperature at which the first solution is mixed with the third solution during the method of chemical coprecipitation is at 50° C., the zero phonon line of the Na₂TiF₆:Mn⁴⁺ red fluoride phosphor with 5 mol % concentration has the maximum intensity.

FIG. 8H is a chart illustrating the relationship between the spectral relatively intensity and the temperature associated with Na₂TiF₆:Mn⁴⁺ with 5 mol % Mn⁴⁺ in accordance with various embodiments of the present disclosure. The temperature in FIG. 8H corresponds to the temperature in FIG. 8A-8G. The spectral relatively intensities of the Na₂TiF₆:Mn⁴⁺ red fluoride phosphor formed at temperature 30° C., 50° C., 100° C., 150° C., 200° C., 250° C., and 300° C. are respectively about 1.0 a.u., 1.02 a.u., 0.92 a.u., 0.78 a.u., 0.58 a.u., 0.28 a.u., and 0.09 a.u.

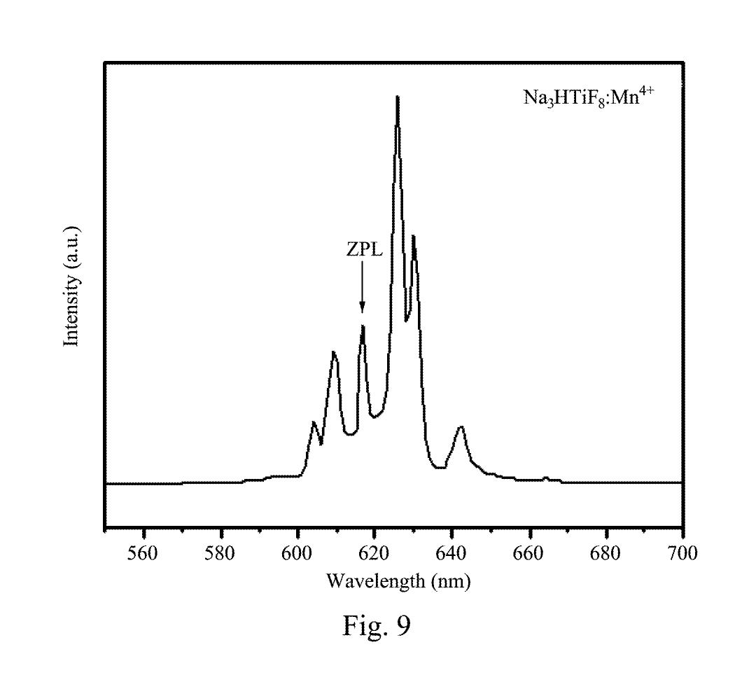

FIG. 9 is a radiation spectrum of Na₃HTiF₈:Mn⁴⁺ in accordance with various embodiments of the present disclosure. In one embodiment, the light emitting element is a light-emitting diode (LED), which may emit light having an excited wavelength in a range of about 400 nm to about 550 nm, and the manganese-doped red fluoride phosphor is a Na₃HTiF₈:Mn⁴⁺ phosphor. The red phosphor may emit a red light having a wavelength in a range of about 600 nm to about 650 nm as shown in FIG. 9 while being excited by the LED. In the emission spectrum of the Na₃HTiF₈:Mn⁴⁺ phosphor, the Na₃HTiF₈:Mn⁴⁺ phosphor has a zero phonon line ZPL, and a peak emission wavelength of the zero phonon line crest is ranged from about 615 nm to about 620 nm.

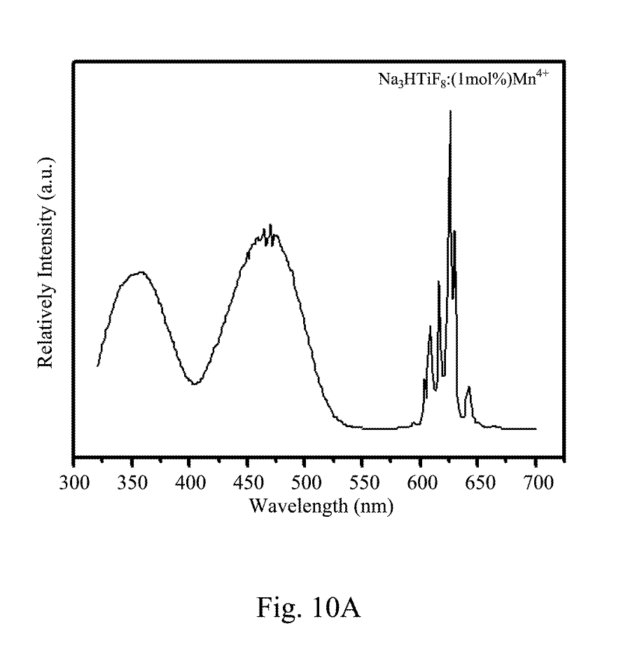

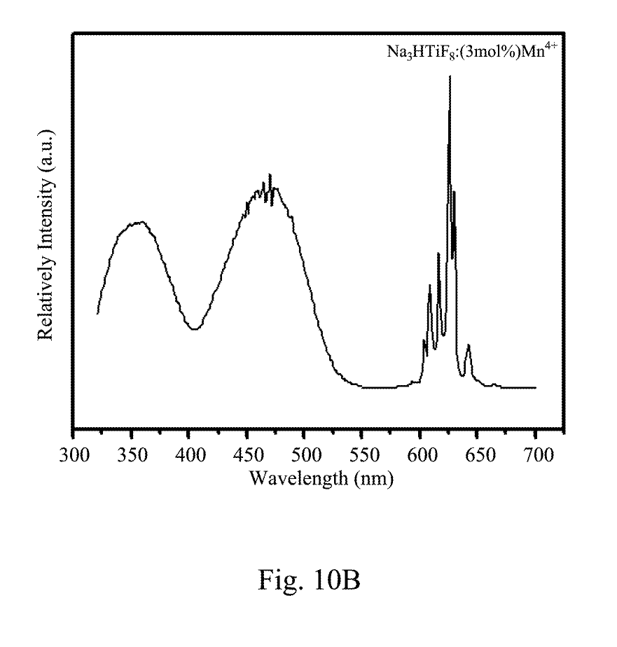

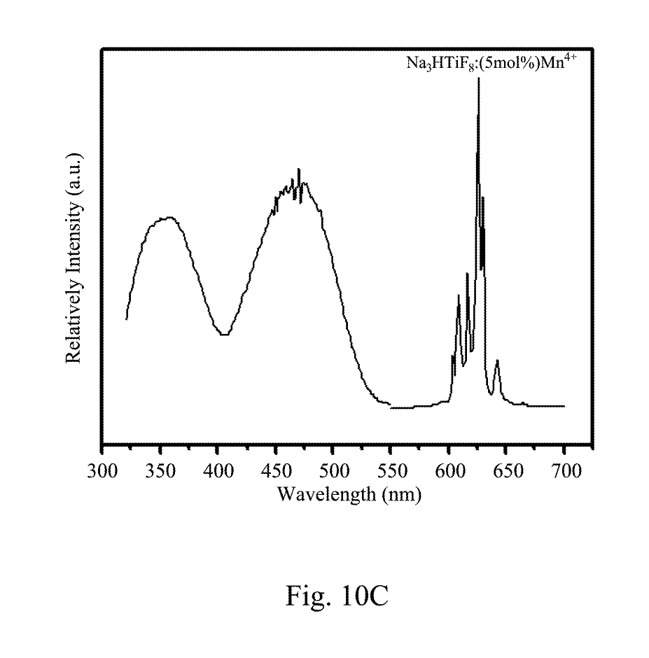

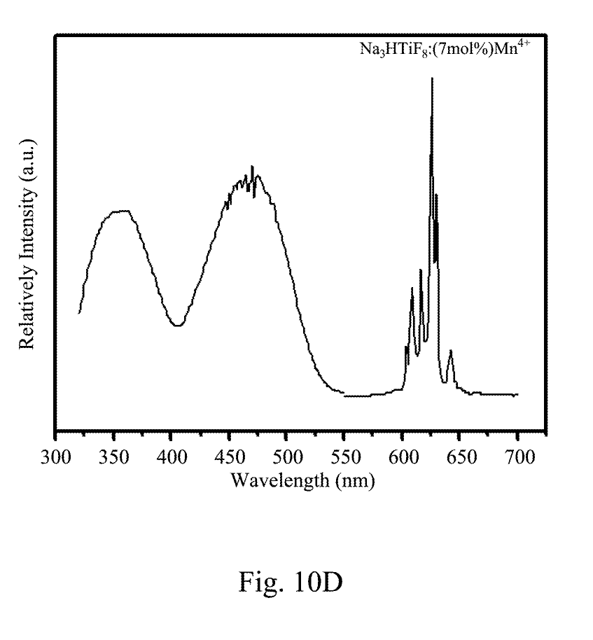

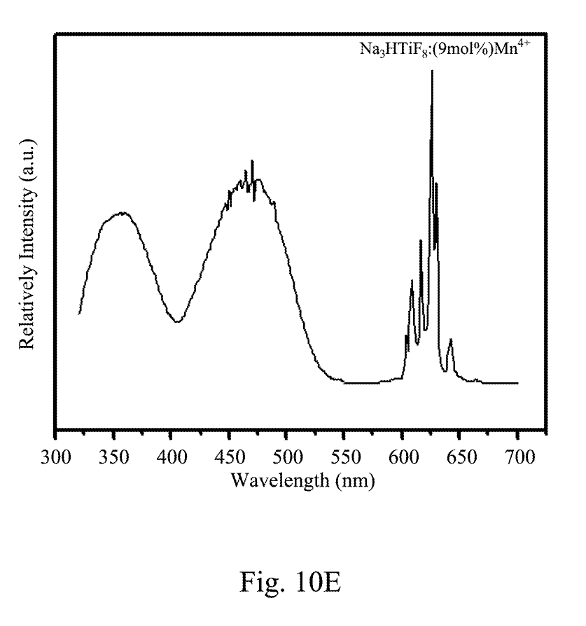

FIG. 10A-10E show radiation spectrum of Na₃HTiF₈:Mn⁴⁺ with different Mn⁴⁺ concentration in accordance with various embodiments of the present disclosure. The Na₃HTiF₈:Mn⁴⁺ red fluoride phosphor has the zero phonon line at the wavelength ranged from about 615 nm to about 620 nm as described above. In FIG. 10A-10E, it can be clearly observed that the zero phonon line of the Na₃HTiF₈:Mn⁴⁺ red fluoride phosphor has the maximum intensity when the concentration of Mn⁴⁺ is 5 mol %.

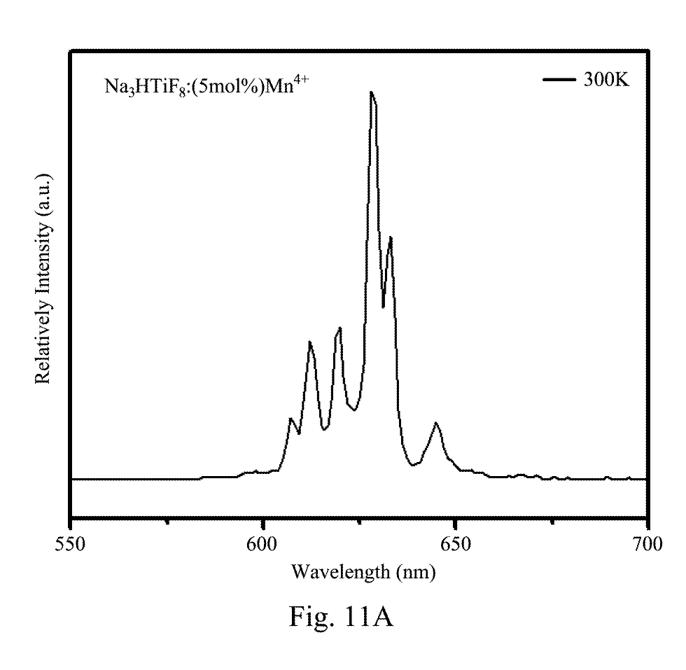

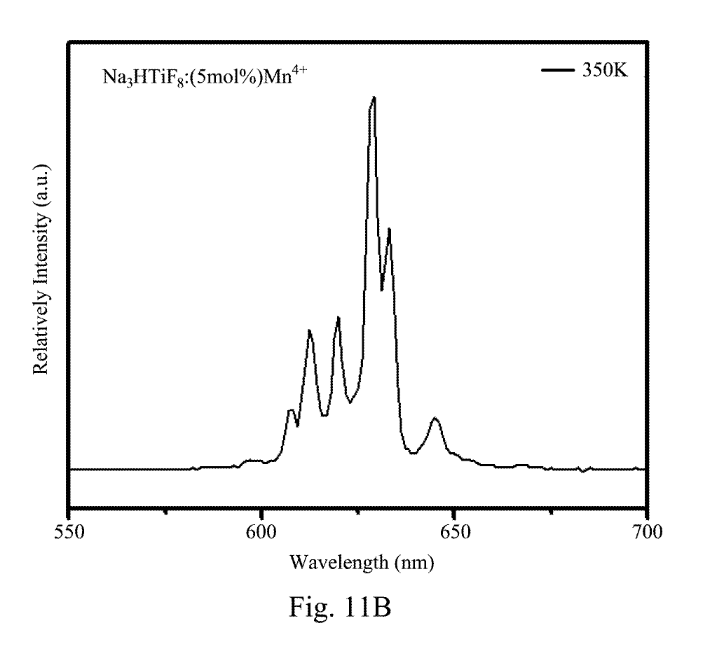

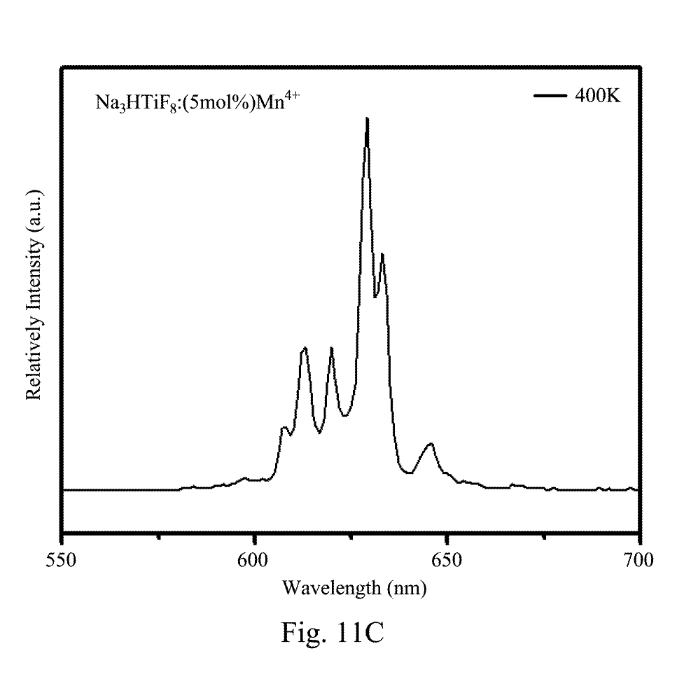

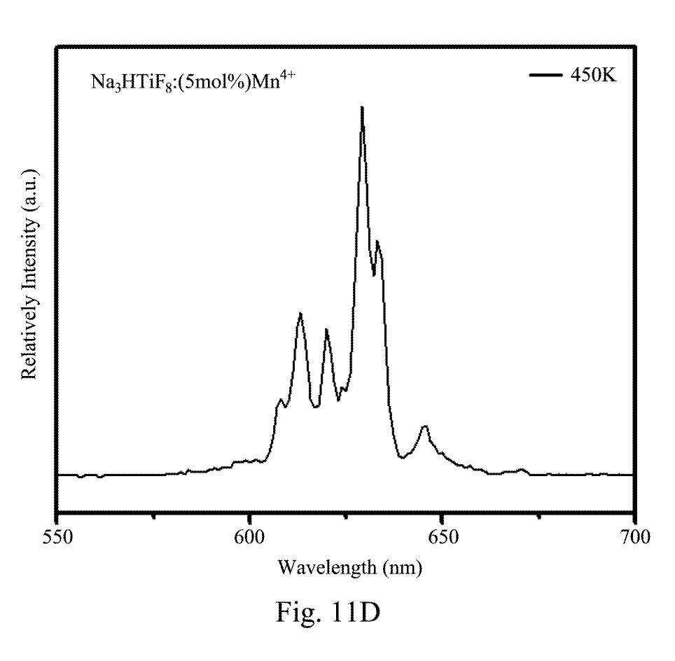

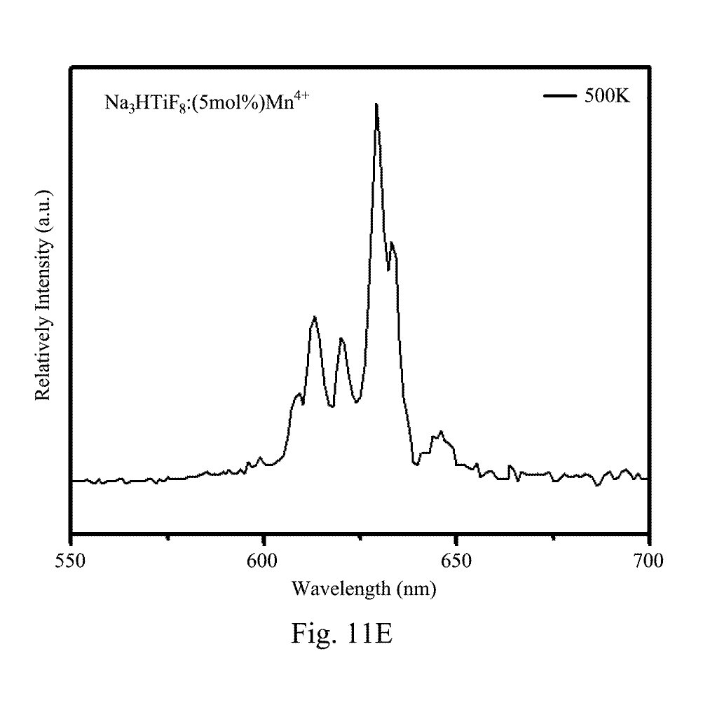

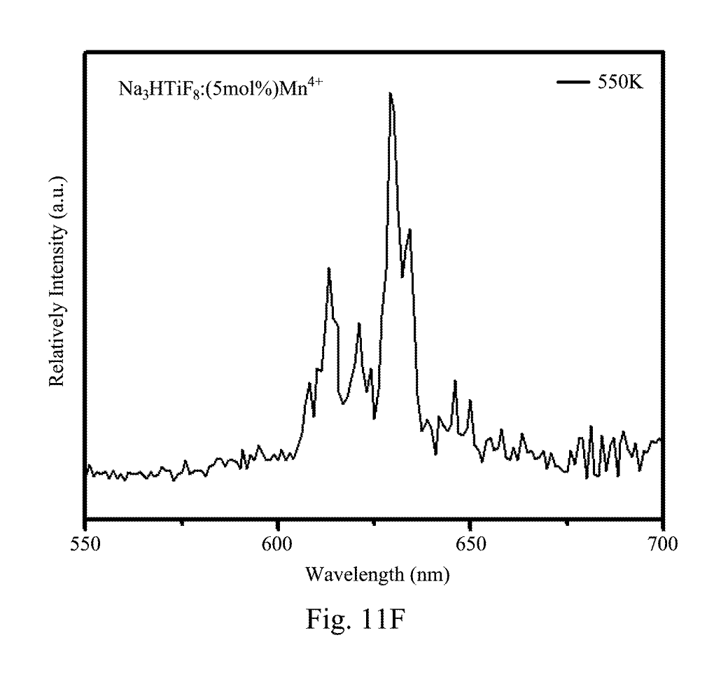

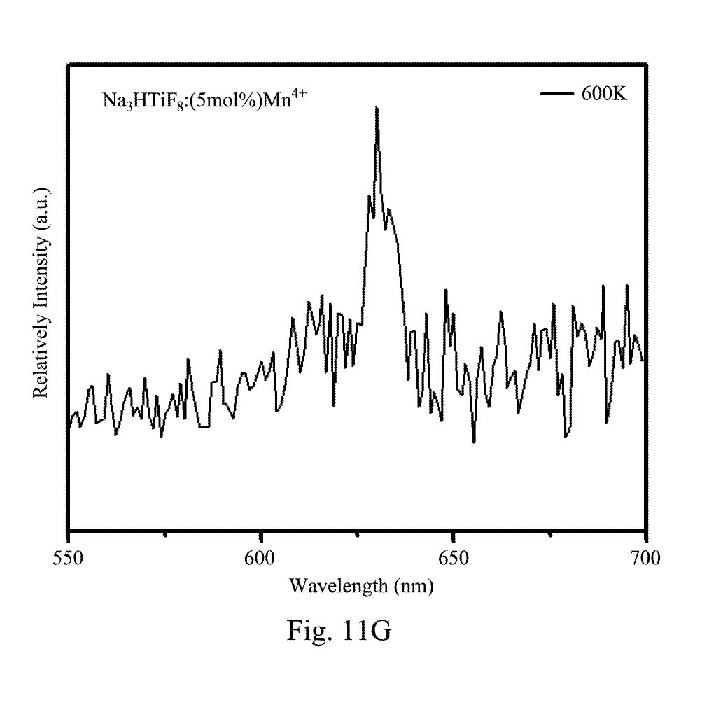

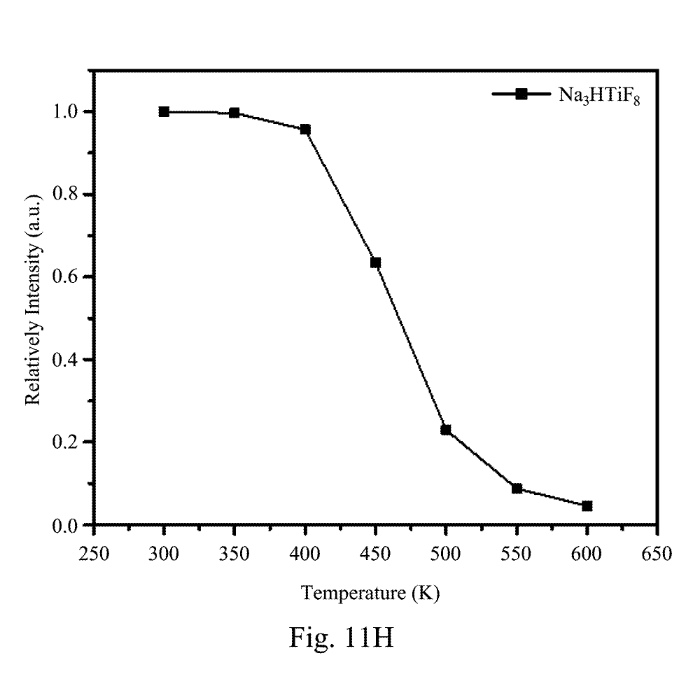

Referring to FIG. 11A-11G, which are radiation spectrums of 5 mol % Mn⁴⁺ of Na₃HTiF₈:Mn⁴⁺ manufactured at different temperatures in accordance with various embodiments of the present disclosure. The Na₃HTiF₈:Mn⁴⁺ red fluoride phosphor has the zero phonon line at the wavelength ranged from about 615 nm to about 620 nm as described above. In FIG. 11A-11G, it can be clearly observed that when the temperature at which the first solution is mixed with the second solution during the method of chemical coprecipitation is at 300K, the zero phonon line of the Na₃HTiF₈:Mn⁴⁺ red fluoride phosphor with 5 mol % Mn⁴⁺ concentration has the maximum intensity.

FIG. 11H is a chart illustrating the relationship between the spectral relatively intensity and the temperature associated with Na₃HTiF₈:Mn⁴⁺ with 5 mol % Mn⁴⁺ in accordance with various embodiments of the present disclosure. The temperature in FIG. 11H corresponds to the temperature in FIG. 11A-11G. The spectral relatively intensities of the Na₃HTiF₈:Mn⁴⁺ red fluoride phosphor formed at temperature 300K, 350K, 400K, 450K, 500K, 550K, and 600K are respectively about 1.0 a.u., 0.996 a.u., 0.957 a.u., 0.633 a.u., 0.229 a.u., 0.088 a.u., and 0.045 a.u.

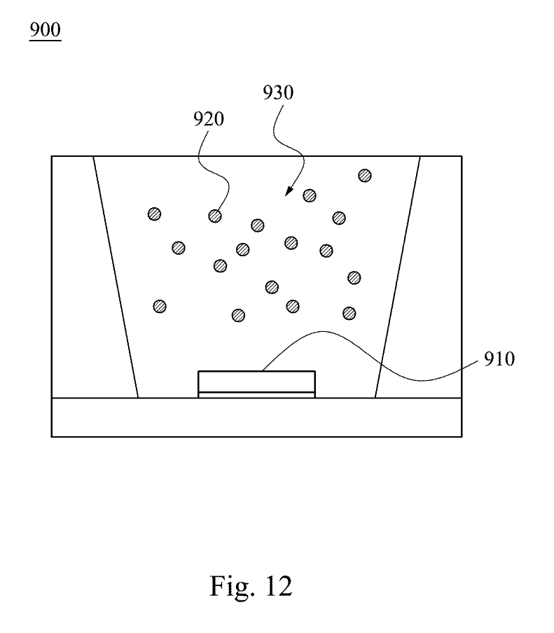

Referring to FIG. 12, the present disclosure also provides a light emitting device 900. The light emitting device 900 includes a light emitting element 910 and a phosphor material 920. The phosphor material 920 may include the manganese-doped red fluoride phosphor described above. The details of the manganese-doped red fluoride phosphor may be the same as or similar to these described above, and thus are not repeated herein. The phosphor material 920 may emit a red light while being excited by the light emitted from the light emitting element 910. For example, the light emitting element 910 may be a light-emitting diode (LED) and emit a blue light with an excitation wavelength in a range of about 420 nm to about 480 nm.

In other embodiments, the phosphor material 920 may further includes one or more other phosphors and/or quantum dots. To be specific, the phosphor material 920 includes an inorganic phosphor and an organic phosphor. More specifically, the inorganic phosphor may be an aluminate phosphor (such as LuYAG, GaYAG, and YAG), a silicate phosphor, a sulfide phosphor, a nitride phosphor, and a fluoride phosphor, but not limited thereto. The organic phosphor may be a monomolecular structure, a multi-molecular structure, an oligomer, or a polymer formed from one or more materials selected from the following compounds, wherein the compound includes a perylene group, a benzimidazole group, a naphthalene group, an anthracene group, a phenanthrene group, a fluorene group, a 9-fluorenone group, a carbazole group, a glutarimide group, a 1,3-diphenylbenzene group, a benzopyrene group, a pyrene group, a pyridine group, a thiophene group, a 2,3-dihydro-1H-benzo[de]isoquinoline-1,3-dione group, and/or a benzimidazole group.

For example, the phosphor material 920 may be, for example, a cerium doped yttrium aluminum garnet (YAG:Ce), and/or a nitrogen oxide contained, silicate contained, a yellow inorganic phosphor containing nitride composition, and/or a yellow organic phosphor.

In one embodiment, the light emitting device 900 includes a blue LED which may emit light with a wavelength of about 420 nm to about 480 nm, a red phosphor having a zero phonon line, and a green phosphor. The red phosphor may be the manganese-doped red fluoride phosphor which is one or more phosphors selected from the group consisting of: (A) A₂[MF₆]:Mn⁴⁺, where A is one or more materials selected from the group consisting of Li, Na, K, Rb, Cs, and NH4, and M comprises one or more materials selected from the group consisting of Ge, Si, Sn, Ti, and Zr; (B) A₃[MF₆]:Mn⁴⁺, where A is one or more materials selected from the group consisting of Li, Na, K, Rb, Cs, and NH4, and M comprises one or more materials selected from the group consisting of Al, Ga, and In; and (C) A₃[HMF₈]:Mn⁴⁺, wherein A is one or more materials selected from the group consisting of Li, Na, K, Rb, Cs, and NH₄, and M comprises one or more materials selected from the group consisting of Ti, Si, and Ge. The green phosphor may be a β-SiAlON green phosphor, a silicate green phosphor, and/or a nitride green phosphor. The red phosphor blended with the green phosphor together may emit white light when being excited by blue light.

In other embodiments, the light emitting device 900 includes a blue LED which may emit light with a wavelength of about 420 nm to about 480 nm, a red phosphor having a zero phonon line, and green quantum dots. The red phosphor may be the manganese-doped red fluoride phosphor which is one or more phosphors selected from the group consisting of: (A) A₂[MF₆]:Mn⁴⁺, where A is one or more materials selected from the group consisting of Li, Na, K, Rb, Cs, and NH4, and M comprises one or more materials selected from the group consisting of Ge, Si, Sn, Ti, and Zr; (B) A₃[MF₆]:Mn⁴⁺, where A is one or more materials selected from the group consisting of Li, Na, K, Rb, Cs, and NH4, and M comprises one or more materials selected from the group consisting of Al, Ga, and In; and (C) A₃[HMF₈]:Mn⁴⁺, wherein A is one or more materials selected from the group consisting of Li, Na, K, Rb, Cs, and NH₄, and M comprises one or more materials selected from the group consisting of Ti, Si, and Ge. The green quantum dots may be CdSe, CdS, CdTe, SInP, InN, AlInN, InGaN, AlGaInN, and/or CuInGaSe. For example, the green quantum dots may be all-inorganic perovskite quantum dots having a chemical formula CsPb(Br_{1-b}I_{b})₃, where 0≤b<0.5. The red phosphor blended with the green quantum dots may emit white light while being excited by blue light.

In other embodiments, the light emitting device 900 includes a blue LED which may emit light with a wavelength of about 420 nm to about 480 nm, a red phosphor having a zero phonon line, and a yellow phosphor. The red phosphor may be the manganese-doped red fluoride phosphor which is one or more phosphors selected from the group consisting of: (A) A₂[MF₆]:Mn⁴⁺, where A is one or more materials selected from the group consisting of Li, Na, K, Rb, Cs, and NH4, and M comprises one or more materials selected from the group consisting of Ge, Si, Sn, Ti, and Zr; (B) A₃[MF₆]:Mn⁴⁺, where A is one or more materials selected from the group consisting of Li, Na, K, Rb, Cs, and NH4, and M comprises one or more materials selected from the group consisting of Al, Ga, and In; and (C) A₃[HMF₈]:Mn⁴⁺, wherein A is one or more materials selected from the group consisting of Li, Na, K, Rb, Cs, and NH₄, and M comprises one or more materials selected from the group consisting of Ti, Si, and Ge. The yellow phosphor may be an aluminate phosphor such as YAG phosphor (Y₃A₁₅O₁₂:Ce³⁺) or a silicate phosphor such as (Sr, Ba)₂SiO₄:Eu²⁺. The red phosphor blended with the yellow phosphor may emit white light while being excited by blue light.

In some embodiments, the light emitting device 900 may further include an encapsulant 930, and the phosphor material 920 described hereinbefore may be dispersed in the encapsulant 930. To be specific, the materials of the encapsulant 930 may include one or more materials selected form the group consisting of polymethyl methacrylate (PMMA), polyethylene terephthalate (PET), polystyrene (PS), polypropylene (PP), polyamide (PA), polycarbonate (PC), polyimide (PI), polydimethylsiloxane (PDMS), epoxy, and silicone.

The present disclosure yet provides a backlight module. The backlight module includes the light emitting device 900 as described above. The details of the light emitting device 900 are the same as or similar to these described above, and thus are not repeated herein.

The present disclosure provides the manganese-doped red fluoride phosphor whose intensity ratio of the zero phonon line crest to the V6 emission crest in the emission spectrum may be effectively adjusted by the distortion degree of the lattice of the manganese-doped red fluoride phosphor to reduce the luminous decay time of the manganese-doped red fluoride phosphor, thereby preventing the human eye from observation of the light residual of the phosphor in the high frequency display.

Although the present invention has been described in considerable detail with reference to certain embodiments thereof, other embodiments are possible. Therefore, the spirit and scope of the appended claims should not be limited thereto the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A manganese-doped red fluoride phosphor having an emission spectrum, the emission spectrum comprising:
a zero phonon line crest having a first peak emission wavelength and a first intensity (I₁); and
a crest having a second peak emission wavelength and a maximum intensity (Iₘₐₓ) except for the zero phonon line crest, wherein the second peak emission wavelength is greater than the first peak emission wavelength, a ratio (I₁/Iₘₐₓ) of the first intensity (I₁) to the maximum intensity (Iₘₐₓ) is ranged from about 0.2 to about 8 such that a luminous decay time of the manganese-doped red fluoride phosphor is less than 10 ms.

2. The manganese-doped red fluoride phosphor of claim 1, wherein the manganese-doped red fluoride phosphor is one or more phosphors selected from the group consisting of:
(A) A₂[MF₆]:Mn⁴⁺, wherein A is one or more materials selected from the group consisting of Li, Na, K, Rb, Cs, and NH₄, and M comprises one or more materials selected from the group consisting of Ge, Si, Sn, Ti, and Zr;
(B) A₃[MF₆]:Mn⁴⁺, wherein A is one or more materials selected from the group consisting of Li, Na, K, Rb, Cs, and NH₄, and M comprises one or more materials selected from the group consisting of Al, Ga, and In; and
(C) A₃[HMF₈]:Mn⁴⁺, wherein A is one or more materials selected from the group consisting of Li, Na, K, Rb, Cs, and NH₄, and M comprises one or more materials selected from the group consisting of Ti, Si, and Ge.

3. The manganese-doped red fluoride phosphor of claim 2, wherein the Mn⁴⁺ in the manganese-doped red fluoride phosphor has a doping ratio ranged from about 0.5 to 20 atom % (at. %).

4. The manganese-doped red fluoride phosphor of claim 2, wherein a concentration of the Mn⁴⁺ in the manganese-doped red fluoride phosphor is ranged from about 3 mol % to about 10 mol %.

5. The manganese-doped red fluoride phosphor of claim 1, wherein the manganese-doped red fluoride phosphor has a chemical formula below:
Na₂SiₓGe₁₋ₓF₆:Mn⁴⁺ or Na₂Ge_{y}Ti_{1-y}F₆:Mn⁴⁺, wherein 0≤x≤1 and 0≤y≤1;
and
Na₃HTi₁₋ₓF₈:Mn⁴⁺, wherein 0<x≤0.09.

6. The manganese-doped red fluoride phosphor of claim 1, wherein the first peak emission wavelength of the zero phonon line crest is ranged from about 615 nm to about 620 nm.

7. The manganese-doped red fluoride phosphor of claim 1, wherein the crest is a V6 emission crest (Stokes shift).

8. A light emitting device, comprising:
a light emitting element; and
a phosphor material, wherein the phosphor material comprises a manganese-doped red fluoride phosphor having an emission spectrum, the emission spectrum comprising:
a zero phonon line crest having a first peak emission wavelength and a first intensity (I₁); and
a crest having a second peak emission wavelength and a maximum intensity (Iₘₐₓ) except for the zero phonon line crest, wherein the second peak emission wavelength is greater than the first peak emission wavelength, a ratio (I₁/Iₘₐₓ) of the first intensity (I₁) to the maximum intensity (Iₘₐₓ) is ranged from about 0.2 to about 8 such that a luminous decay time of the manganese-doped red fluoride phosphor is less than 10 ms.

9. The light emitting device of claim 8, wherein the phosphor material further comprises one or more phosphors and/or quantum dots.

10. The light emitting device of claim 9, wherein the light emitting device further comprises an encapsulant, and the phosphor material is dispersed in the encapsulant.

11. The light emitting device of claim 8, wherein the manganese-doped red fluoride phosphor is one or more phosphors selected from the group consisting of:
(A) A₂[MF₆]:Mn⁴⁺, wherein A is one or more materials selected from the group consisting of Li, Na, K, Rb, Cs, and NH4, and M comprises one or more materials selected from the group consisting of Ge, Si, Sn, Ti, and Zr;
(B) A₃[MF₆]:Mn⁴⁺, wherein A is one or more materials selected from the group consisting of Li, Na, K, Rb, Cs, and NH4, and M comprises one or more materials selected from the group consisting of Al, Ga, and In; and
(C) A₃[HMF₈]:Mn⁴⁺, wherein A is one or more materials selected from the group consisting of Li, Na, K, Rb, Cs, and NH₄, and M comprises one or more materials selected from the group consisting of Ti, Si, and Ge.

12. The light emitting device of claim 11, wherein the Mn⁴⁺ in the manganese-doped red fluoride phosphor has a doping ratio ranged from about 0.5 to 20 atom % (at. %).

13. The light emitting device of claim 11, wherein a concentration of the Mn⁴⁺ in the manganese-doped red fluoride phosphor is ranged from about 3 mol % to about 10 mol %.

14. The light emitting device of claim 8, wherein the manganese-doped red fluoride phosphor has a chemical formula below:
Na₂SiₓGe₁₋ₓF₆:Mn⁴⁺ or Na₂Ge_{y}Ti_{1-y}F₆:Mn⁴⁺, wherein 0≤x≤1 and 0≤y≤1;
and
Na₃HTi₁₋ₓF₈:Mn⁴⁺, wherein 0<x≤0.09.

15. The light emitting device of claim 8, wherein the first peak emission wavelength of the zero phonon line crest is ranged from about 615 nm to about 620 nm.

16. The light emitting device of claim 8, wherein the crest is a V6 emission crest (Stokes shift).

17. A backlight module, comprising the light emitting device as claimed in claim 8.

18. The backlight module of claim 17, wherein the manganese-doped red fluoride phosphor is one or more phosphors selected from the group consisting of:
(A) A₂[MF₆]:Mn⁴⁺, wherein A is one or more materials selected from the group consisting of Li, Na, K, Rb, Cs, and NH4, and M comprises one or more materials selected from the group consisting of Ge, Si, Sn, Ti, and Zr;
(B) A₃[MF₆]:Mn⁴⁺, wherein A is one or more materials selected from the group consisting of Li, Na, K, Rb, Cs, and NH4, and M comprises one or more materials selected from the group consisting of Al, Ga, and In; and
(C) A₃[HMF₈]:Mn⁴⁺, wherein A is one or more materials selected from the group consisting of Li, Na, K, Rb, Cs, and NH₄, and M comprises one or more materials selected from the group consisting of Ti, Si, and Ge.

19. The backlight module of claim 18, wherein the Mn⁴⁺ in the manganese-doped red fluoride phosphor has a doping ratio ranged from about 0.5 to 20 atom % (at. %).

20. The backlight module of claim 17, wherein the manganese-doped red fluoride phosphor has a chemical formula below:
Na₂SiₓGe₁₋ₓF₆:Mn⁴⁺ or Na₂Ge_{y}Ti_{1-y}F₆:Mn⁴⁺, wherein 0≤x≤1 and 0≤y≤1;
and
Na₃HTi₁₋ₓF₈:Mn⁴⁺, wherein 0<x≤0.09.
